(19) United States
(12) Patent Application Publication
(10) Pub. No.: US 2020/0350449 A1
(43) Pub. Date: Nov. 5, 2020

(54) Monolithic Photovoltaics in Series on Insulating Substrate

(71) Applicant: International Business Machines Corporation, Armonk, NY (US)

(72) Inventors: Ning Li, White Plains, NY (US); Devendra K. Sadana, Pleasantville, NY (US); William T. Spratt, Croton-on-Hudson, NY (US); Ghavam Shahidi, Pound Ridge, NY (US)

(21) Appl. No.: 16/401,863

(22) Filed: May 2, 2019

(51) Int. Cl. H01L 31/0475; H01L 31/0304; H01L 31/0392; H01L 31/05; H01L 31/0735; H01L 31/18

(52) U.S. Cl. CPC H01L 31/0475; H01L 31/03042; H01L 31/03046; H01L 31/03048; H01L 31/1848; H01L 31/0504; H01L 31/0735; H01L 31/1844; H01L 31/0392

(57) ABSTRACT

Monolithic, lateral series photovoltaic and photodiode devices on an insulating substrate are provided. In one aspect, a method of forming a photovoltaic device includes: forming a photovoltaic stack on an insulating substrate that includes: a bottom contact layer disposed on the insulating substrate, a BSF layer disposed on the bottom contact layer, a junction layer disposed on the BSF layer, a window layer disposed on the junction layer, and a top contact layer disposed on the window layer; patterning the top contact layer, the window layer, the junction layer, the BSF layer and the bottom contact layer into individual device stacks; forming contact pads on patterned portions of the bottom/top contact layers in each of the device stacks; and forming interconnects in contact with the contact pads that serially connect the device stacks. A photovoltaic device is also provided.

### FIELD OF THE INVENTION

The present invention relates to photovoltaic-based devices, and more particularly, to separate monolithic photovoltaic and photodiode devices in series on an insulating substrate and techniques for fabrication thereof.

### BACKGROUND OF THE INVENTION

The internet of things (IoT) is a network of interconnected devices, many of which are mobile devices needing a reliable power source. Photovoltaic cells provide an ideal power source solution for many IoT applications.

The photovoltaic cells for IoT applications are often required to be physically small, yet achieve the high voltages needed to drive signal components such as light emitting diodes (LEDs) and memory cells, as well as charge the device's battery. Multiple voltage level output is often also needed for IoT circuit systems. For efficiency, this multiple voltage level output is preferably provided by the photovoltaic cell directly, rather than requiring a separate voltage converter component.

Thus, improved photovoltaic-based devices for use in applications such as IoT would be desirable.

### SUMMARY OF THE INVENTION

The present invention provides monolithic, lateral series photovoltaic and separate photodiode devices on an insulating substrate and techniques for fabrication thereof. In one aspect of the invention, a method of forming a photovoltaic device is provided. The method includes: forming a photovoltaic stack on an insulating substrate, the photovoltaic stack including: a bottom contact layer disposed on the insulating substrate, a back surface field (BSF) layer disposed on the bottom contact layer, a junction layer disposed on the BSF layer, a window layer disposed on the junction layer, and a top contact layer disposed on the window layer; patterning the top contact layer, the window layer, the junction layer, the BSF layer and the bottom contact layer into individual device stacks; forming contact pads on patterned portions of the bottom contact layer and the top contact layer in each of the device stacks; and forming interconnects in contact with the contact pads that serially connect the device stacks.

In another aspect of the invention, a photovoltaic device is provided. The photovoltaic device includes: an insulating substrate; device stacks on the insulating substrate, wherein each of the device stacks includes: a bottom contact layer disposed on the insulating substrate, a BSF layer disposed on the bottom contact layer, a junction layer disposed on the BSF layer, a window layer disposed on the junction layer, and a top contact layer disposed on the window layer; contact pads formed on the bottom contact layer and the top contact layer in each of the device stacks; and interconnects in contact with the contact pads that serially connect the device stacks.

A more complete understanding of the present invention, as well as further features and advantages of the present invention, will be obtained by reference to the following detailed description and drawings.

### BRIEF DESCRIPTION OF THE DRAWINGS

FIG. 1 is a schematic diagram illustrating an exemplary configuration of the present device having serially-connected photovoltaic (PV) cells for power generation, and a photodiode (PD) for signal receiving according to an embodiment of the present invention;

FIG. 2 is a cross-sectional diagram illustrating an insulating substrate (e.g., germanium (Ge)-on-insulator wafer), and layers of a photovoltaic stack having been deposited sequentially, one on top of the other, onto the insulating substrate according to an embodiment of the present invention;

FIG. 3 is a cross-sectional diagram illustrating the photovoltaic stack having been patterned into individual device stacks according to an embodiment of the present invention;

FIG. 4 is a cross-sectional diagram illustrating an isolation etch having been performed according to an embodiment of the present invention;

FIG. 5 is a cross-sectional diagram illustrating a surface passivation layer having been formed on the device stacks according to an embodiment of the present invention;

FIG. 6 is a cross-sectional diagram illustrating contact pads having been formed on bottom and top contact layers of each of the device stacks according to an embodiment of the present invention;

FIG. 7 is a cross-sectional diagram illustrating a (first) photoresist mask having been patterned over the device stacks according to an embodiment of the present invention;

FIG. 8 is a cross-sectional diagram illustrating a thin seed layer of a contact metal having been deposited onto the device stacks over the first photoresist mask according to an embodiment of the present invention;

FIG. 9 is a cross-sectional diagram illustrating a second photoresist mask having been patterned over the device stacks covering the seed layer everywhere but where interconnects will be formed, and a contact metal having been plated onto the exposed areas of the seed layer according to an embodiment of the present invention;

FIG. 10 is a cross-sectional diagram illustrating the seed layer and any excess contact metal having been removed along with first/second photoresist masks leaving behind interconnects in contact with the contact pads according to an embodiment of the present invention;

FIG. 11 is a cross-sectional diagram illustrating, according to an alternative embodiment, a substrate (e.g., a GaAs/AlAs substrate), and layers of a photovoltaic stack having been deposited sequentially, one on top of the other, onto the substrate according to an embodiment of the present invention;

FIG. 12 is a cross-sectional diagram illustrating the photovoltaic stack having been patterned into individual device stacks according to an embodiment of the present invention;

FIG. 13 is a cross-sectional diagram illustrating an isolation etch having been performed according to an embodiment of the present invention;

FIG. 14 is a cross-sectional diagram illustrating a surface passivation layer having been formed on the device stacks, contact pads having been formed on bottom and top contact layers of each of the device stacks, and interconnects having been formed in contact with the contact pads according to an embodiment of the present invention;

FIG. 15 is a cross-sectional diagram illustrating lateral oxidation having been used to convert the (e.g., AlAs) into oxide insulator (e.g., Al₂O₃) according to an embodiment of the present invention; and

FIG. 16 is a schematic diagram illustrating an exemplary computing device according to an embodiment of the present invention.

### DETAILED DESCRIPTION OF PREFERRED EMBODIMENTS

Provided herein are monolithic, lateral series photovoltaic devices on an electrically insulating substrate. The present devices are ideal for applications such as internet of things (IoT) which often require mobility, as well as high, multi-level voltage output.

For instance, as will be described in detail below, the present photovoltaic devices include at least one multijunction photovoltaic cell in combination with at least one signal device such as a photodiode for separate power generation and signal receiving, respectively. The devices are formed laterally on a common insulating substrate.

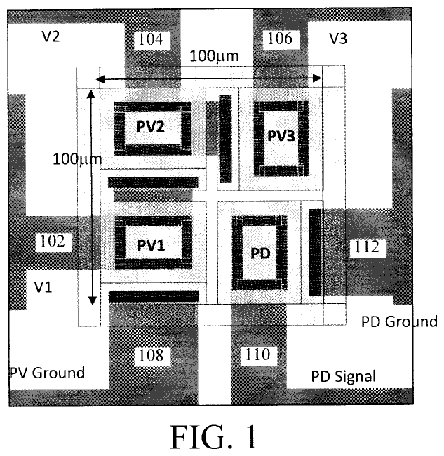

For instance, FIG. 1 is a schematic diagram of an exemplary configuration of the present device having three photovoltaic (PV) cells (labeled “PV1,” “PV2” and “PV3”) connected in series for power generation, and a separate photodiode (labeled “PD”) for signal receiving. In this example, three different voltage levels V1, V2 and V3 can be extracted from PV1, PV2 and PV3, via contact lines 102, 104 and 106, respectively, where, e.g., V1<V2<V3. Namely, since the contact lines are attached at the serial connection points of PV1, PV2 and PV3, each contact line 102, 104 and 106 will output a different voltage (from the other contact lines) depending on how many junctions are serially connected between each given contact line and ground. For instance, by way of example only, when an indium gallium phosphide (InGaP) junction is employed, V1, V2 and V3 can be about 1.4 volts (V), about 2.8V and about 4.2V, respectively. Changing the junction affects the multi-level voltage output. For instance, when a gallium arsenide (GaAs) junction is employed, V1, V2 and V3 can be about 1V, about 2V and about 3V, respectively.

A ground line 108 provides a connection to ground (labeled “PV Ground”) for the serially-connected photovoltaic devices PV1, PV2 and PV3. Optical signals are provided to the photodiode PD via signal line 110. A ground line 112 provides a connection to ground (labeled “PD Ground”) for the photodiode PD. According to an exemplary embodiment, the contact lines 102, 104 and 106, ground lines 108 and 112, and signal line 110 are each metal lines formed using a standard metallization process.

Generally, a photovoltaic cell produces free electrons and/or vacancies, i.e., holes, when exposed to radiation, such as light, which results in the production of an electric current. A multijunction photovoltaic cell includes multiple junctions of a semiconductor layer of a p-type conductivity that shares an interface with a semiconductor layer of an n-type conductivity, in which the interface provides an electrical junction.

A photodiode is a p-n junction or a PIN structure having an undoped intrinsic semiconductor region between p-type and n-type semiconductor regions. When a photon of sufficient energy strikes the photodiode, it creates an electron-hole pair via the inner photoelectric effect. If the absorption occurs in the depletion region of the p-n junction, or one diffusion length away from it, these carriers are swept from the junction by the built-in electric field of the depletion region, producing a photocurrent. The photodiode provided by the p-n junction may be employed as an optical receiver, whereby the photodiode generates a given output in response to an incident light signal.

It is notable that, with conventional designs, photocurrent leakage through the substrate poses a significant problem for serially connected cells. Namely, when there is photoconductivity through the substrate the voltages from the serially-connected cells add up, making conventional designs plausible only for low light applications.

Advantageously, the present techniques employ an improved insulating substrate based, for example, on a semiconductor-on-insulator (SOI) or III-V configuration. Generally, a SOI wafer includes an SOI layer separated from an underlying substrate by a buried insulator. When the buried insulator is an oxide it is also referred to as a buried oxide or BOX. The SOI layer can include any suitable semiconductor, such as silicon (Si), germanium (Ge), silicon germanium (SiGe) and/or a III-V semiconductor. As will be described in detail below, according to one exemplary embodiment, a germanium (Ge)-on-insulator or GeOI wafer is employed. According to another alternative exemplary embodiment described in detail below, a III-V substrate is employed and lateral oxidation is used to form an insulating oxide layer on the III-V substrate.

The term “III-V,” as used herein, refers to a material that includes at least one group III element and at least one group V element selected from the period table of elements. By way of example only, in accordance with the present techniques, suitable III-V materials include, but are not limited to, aluminum arsenide (AlAs), aluminum gallium arsenide (AlGaAs), aluminum gallium nitride (AlGaN), indium aluminum arsenide (InAlAs), aluminum nitride (AlN), gallium antimonide (GaSb), gallium arsenide (GaAs), gallium nitride (GaN), indium antimonide (InSb), indium arsenide (InAs), indium gallium arsenide (InGaAs), indium gallium nitride (InGaN), indium gallium phosphide (InGaP), indium nitride (InN), indium phosphide (InP) and/or indium gallium arsenide phosphide (InₓGa₁₋ₓAs_{y}P_{1-y}).

As will be described in detail below, the present multilayer devices will be fabricated monolithically on an insulating substrate by sequentially forming one layer on top of the other. According to an exemplary embodiment, an epitaxial process is employed to deposit the layers. For the growth to be epitaxial, each layer needs to be deposited onto a layer having a similar lattice constant. For instance, Ge has a lattice constant that is very close to that of GaAs. See, for example, Barrutia et al., “Effect of Ge autodoping during III-V MOVPE growth on Ge substrates,” Journal of Crystal Growth, volume 475, (October 2017) (19 pages), the contents of which are incorporated by reference as if fully set forth herein. Thus, a GeOI wafer is an ideal means for providing both a Ge substrate onto which to grow a III-V device stack, as well as an underlying buried insulator. Alternatively, starting the process with a III-V substrate also can provide a lattice matched substrate for III-V growth, followed by conversion of the growth substrate to an insulator.

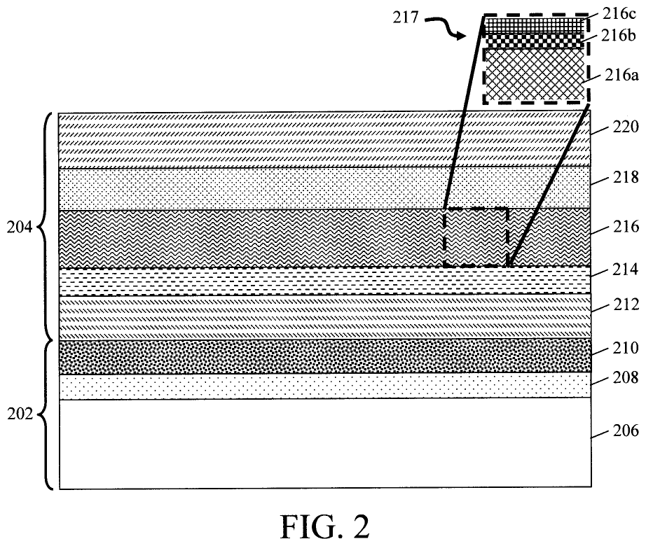

An exemplary embodiment methodology for fabricating the present photovoltaic-based device on a SOI substrate is now described by way of reference to FIGS. 2-10. As shown in FIG. 2, the process begins with a substrate 202 on which a photovoltaic stack 204 is formed.

As highlighted above, a SOI wafer includes an SOI layer 210 separated from an underlying substrate 206 by a buried insulator 208 such as a buried oxide or BOX. Generally, the SOI layer 210 can include any suitable semiconductor, Si, Ge, SiGe and/or a III-V semiconductor. According to an exemplary embodiment, SOI layer 210 includes Ge. This particular type of SOI wafer configuration is also referred to herein as a Ge-on-insulator or GeOI wafer. By way of example only, in one exemplary embodiment, the 501 layer 210 has a Ge percentage (Ge %) of from about 50% Ge to about 100% Ge (i.e., pure Ge) and ranges therebetween with the balance, if any, being Si.

The layers of photovoltaic stack 204 are then deposited sequentially, one on top of the other, onto the substrate 202. According to an exemplary embodiment, the photovoltaic stack 204 includes, but is not limited to, a bottom contact layer 212 disposed on the SOI layer 210, back surface field (BSF) layer 214 disposed on the bottom contact layer 212, junction layer 216 disposed on the BSF layer 214, window layer 218 disposed on the junction layer 216, and top contact layer 220 disposed on the window layer 218.

Bottom contact layer 212 can be formed from one or more of the III-V materials provided above. For instance, according to an exemplary embodiment, bottom contact layer 212 is formed from GaAs. Optionally, the III-V material(s) used for bottom contact layer 212 is doped with at least one electrically-active impurity such as Si, e.g., Si:GaAs. These impurities serve as electron donors and/or acceptors. Impurities like Si are amphoteric and serve as both donors and acceptors. In one exemplary embodiment, the bottom contact layer 212 is doped with an impurity such as Si at a concentration of from about 5×10¹⁸ molar (atomic) percent (at. %) to about 8×10¹⁸ at. % and ranges therebetween. According to an exemplary embodiment, doping with impurities such as Si or Zn (see below) is performed in-situ, i.e., during growth of the given layer.

Bottom contact layer 212 can be deposited onto substrate 202 using an epitaxial growth process (such as molecular beam epitaxy (MBE)), a chemical vapor deposition (CVD) process such as metalorganic chemical vapor deposition (MOCVD), or atomic layer deposition (ALD). According to an exemplary embodiment, bottom contact layer 212 is formed having a thickness of from about 20 nanometers (nm) to about 30 nm and ranges therebetween, e.g., 30 nm. It is notable that the various layers, structures, etc. depicted in the figures are not necessarily drawn to scale.

Use of back surface field layer (BSF) layer 214 helps to reduce electron-hole recombination at the back surface of a photovoltaic device, thus increasing efficiency. BSF layer 214 can be formed from one or more of the III-V materials provided above. For instance, according to an exemplary embodiment, BSF layer 214 is formed from InGaP. Optionally, the III-V material(s) used for BSF layer 214 is doped with at least one electrically-active impurity such as zinc (Zn), e.g., Zn:InGaP. Group II impurities like Zn serve as electron acceptors. In one exemplary embodiment, BSF layer 214 is doped with an impurity such as Zn at a concentration of from about 1×10¹⁸ at. % to about 5×10¹⁸ at. % and ranges therebetween.

BSF layer 214 can be deposited onto bottom contact layer 212 using an epitaxial process (e.g., MBE), CVD (e.g., MOCVD) or ALD. According to an exemplary embodiment, BSF layer 214 is formed having a thickness of from about 80 nm to about 120 nm and ranges therebetween, e.g., 100 nm.

According to an exemplary embodiment, junction layer 216 includes multiple layers of the III-V materials provided above, such as a base layer 216a disposed on BSF layer 214, a setback layer 216b disposed on base layer 216a, and an emitter layer 216c disposed on the setback layer 216b. See, e.g., expanded view 217 in FIG. 2.

Base layer 216a can be formed from one or more of the III-V materials provided above. For instance, according to an exemplary embodiment, base layer 216a is formed from GaAs. Optionally, the III-V material(s) used for base layer 216a is doped with at least one electrically-active impurity such as Zn, e.g., Zn:GaAs. In one exemplary embodiment, base layer 216a is doped with an impurity such as Zn at a concentration of from about 1×10¹⁷ at. % to about 2×10¹⁷ at. % and ranges therebetween.

Base layer 216a can be deposited onto BSF layer 214 using an epitaxial process (e.g., MBE), CVD (e.g., MOCVD) or ALD. According to an exemplary embodiment, base layer 216a is formed having a thickness of from about 0.5 micrometers (μm) to about 1.5 μm and ranges therebetween, e.g., 1.0 μm.

Use of a setback layer 216b serves to improve the emitter injection efficiency and reduce the impurity out-diffusion from the base layer 216a to the emitter layer 216c. See, for example, Liou et al., “An Analytical Model for Current Transport in AlGaAs/GaAs abrupt HBTs with a Setback Layer,” Solid-State Electronics 36(6):819-825 (June 1993), Abstract (1 page), the contents of which are incorporated by reference as if fully set forth herein. Setback layer 216b can be formed from one or more of the III-V materials provided above. For instance, according to an exemplary embodiment, setback layer 216b is formed from intrinsic (undoped) GaAs.

Setback layer 216b can be deposited onto base layer 216a using an epitaxial process (e.g., MBE), CVD (e.g., MOCVD) or ALD. According to an exemplary embodiment, setback layer 216b is formed having a thickness of from about 5 nm to about 15 nm and ranges therebetween, e.g., 10 nm.

Emitter layer 216c can be formed from one or more of the III-V materials provided above. For instance, according to an exemplary embodiment, emitter layer 216c is formed from GaAs. Optionally, the III-V material(s) used for emitter layer 216c is doped with at least one electrically-active impurity such as Si, e.g., Si:GaAs. In one exemplary embodiment, emitter layer 216c is doped with an impurity such as Si at a concentration of from about 1×10¹⁸ at. % to about 2×10¹⁸ at. % and ranges therebetween.

Emitter layer 216c can be deposited onto setback layer 216b using an epitaxial process (e.g., MBE), CVD (e.g., MOCVD) or ALD. According to an exemplary embodiment, emitter layer 216c is formed having a thickness of from about 80 nm to about 120 nm and ranges therebetween, e.g., 100 nm.

Window layer 218 can be formed from one or more of the III-V materials provided above. For instance, according to an exemplary embodiment, window layer 218 is formed from AlGaAs, e.g., Al_{0.6}Ga_{0.4}As. Optionally, the III-V material(s) used for window layer 218 is doped with at least one electrically-active impurity such as Si, e.g., Si:Al_{0.6}Ga_{0.4}As. In one exemplary embodiment, window layer 218 is doped with an impurity such as Si at a concentration of from about 2×10¹⁸ at. % to about 4×10¹⁸ at. % and ranges therebetween.

Window layer 218 can be deposited onto junction layer 216 using an epitaxial process (e.g., MBE), CVD (e.g., MOCVD) or ALD. According to an exemplary embodiment, window layer 218 is formed having a thickness of from about 180 nm to about 220 nm and ranges therebetween, e.g., 200 nm.

Like bottom contact layer 212, top contact layer 220 can be formed from one or more of the III-V materials provided above. For instance, according to an exemplary embodiment, top contact layer 220 is formed from GaAs. Optionally, the III-V material(s) used for top contact layer 220 is doped with at least one electrically-active impurity such as Si, e.g., Si:GaAs. In one exemplary embodiment, the top contact layer 220 is doped with an impurity such as Si at a concentration of from about 5×10¹⁸ at. % to about 8×10¹⁸ at. % and ranges therebetween.

Top contact layer 220 can be deposited onto window layer 218 using an epitaxial process (e.g., MBE), CVD (e.g., MOCVD) or ALD. According to an exemplary embodiment, top contact layer 220 is formed having a thickness of from about 20 nm to about 30 nm and ranges therebetween, e.g., 30 nm.

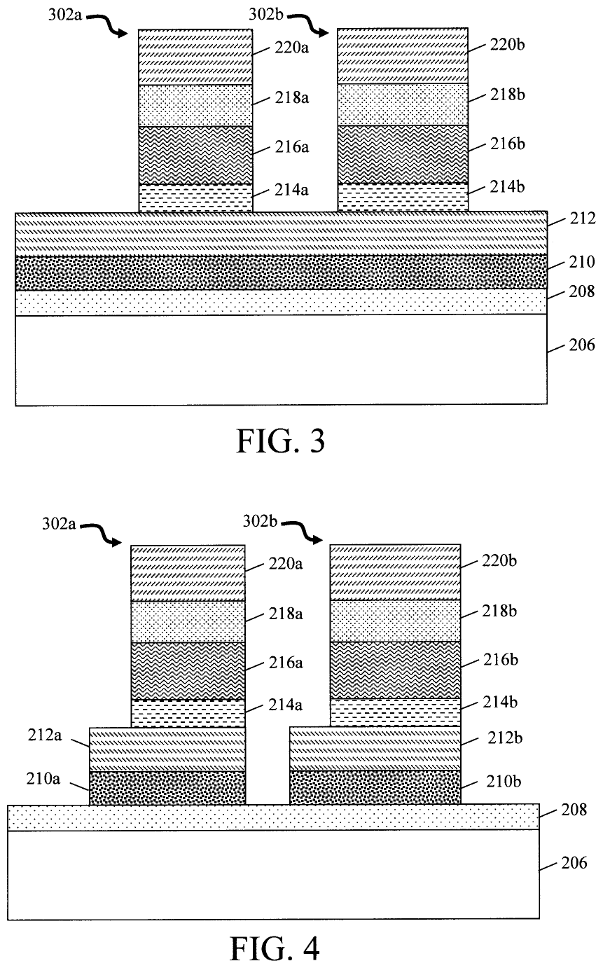

Standard lithography and etching techniques are then used to pattern the photovoltaic stack 204 into individual device stacks 302a, 302b, etc. See FIG. 3. A directional (anisotropic) etching process such as reactive ion etching (RIE) can be used for the device stack etch. As shown in FIG. 3, each device stack 302a,b, etc. extends down through the top contact layer 220, window layer 218, junction layer 216 and BSF layer 214. The patterned portions of each of these layers in device stacks 302a/302b are now given the reference numerals 220a/220b, 218a/218b, 216a/216b and 214a/214b, respectively.

Device stacks 302a and 302b form separate multilayer three-dimensional (3D) monolithic photovoltaic devices that, as will be described in detail below, can each serve as a photovoltaic (PV) cell or photodiode (PD) device on the (common) insulating substrate 202. Thus, as will be described below, the present devices can be employed for a combination of power generation (photovoltaic cell) and signal receiving (photodiode). For instance, using the configuration shown in FIG. 1 (described above) as an example, interconnects can be formed to serially connect those devices that will serve as photovoltaic cells for multilevel power generation.

An isolation etch is next performed to pattern the bottom contact layer 212 and SOI layer 210 in the device stacks 302a/302b. Again, standard lithography and etching techniques using, e.g., a directional (anisotropic) etching process such as RIE, can be employed for the isolation etch. The patterned portions of each of these layers in device stacks 302a/302b are now given the reference numerals 212a/212b and 210a/210b, respectively. As shown in FIG. 4, device stacks 302a/302b are now isolated by buried insulator 208.

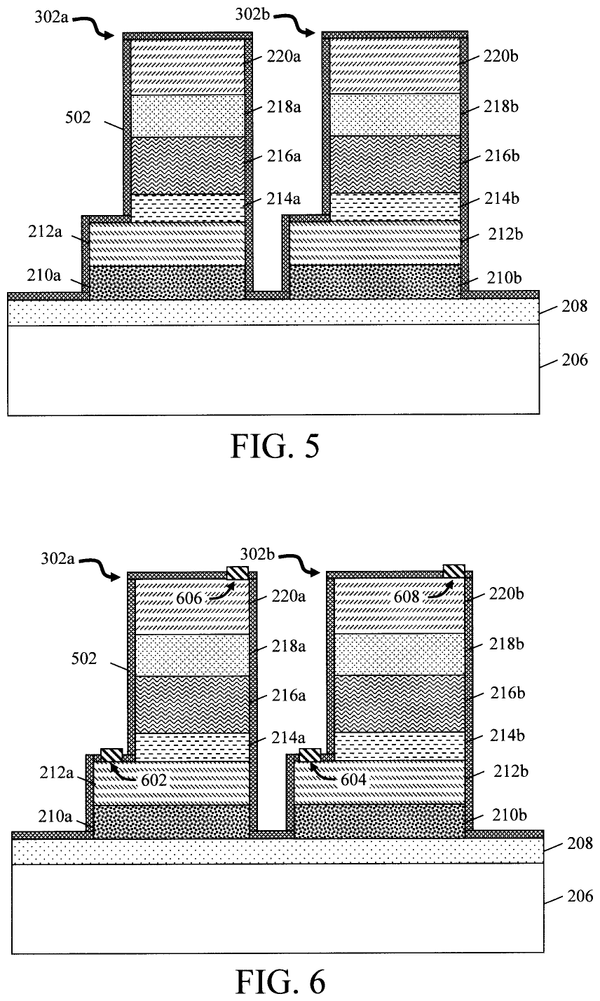

Surface passivation helps improve photovoltaic device efficiency. Namely, surface passivation reduces the defects on device surfaces which helps to reduce unwanted carrier recombination at those defect sites. Thus, as shown in FIG. 5, a conformal surface passivation layer 502 is next formed on the top/sidewalls of device stacks 302a/302b, as well as on the exposed upper surface of buried insulator 208. By way of example only, suitable materials for passivation layer 502 include, but are not limited to, aluminum oxide (Al₂O₃) deposited using a process such as CVD. See, for example, U.S. Patent Application Publication Number 2017/0287715 by Deshazer et al., entitled “Aluminum Oxide Passivation for Solar Cells,” the contents of which are incorporated by reference as if fully set forth herein.

Contact pads 602/604 and 606/608 are then formed on bottom contacts 212a/212b and top contacts 220a/220b of device stacks 302a and 302b, respectively. See FIG. 6. By way of example only, contact pads 602/604 and 606/608 can be formed using a lift-off process or other standard metallization technique such as sputtering or evaporation of a contact metal or metals through a shadow mask. Suitable contact metals include, but are not limited to, copper (Cu), aluminum (Al), tungsten (W), titanium (Ti), platinum (Pd), nickel (Ni) and/or palladium (Pd).

Interconnects are then formed to the contact pads 602/604 and 606/608. In the present example, the interconnects formed will serially connect the device stacks 302a and 302b. The device stacks that are serially connected serve as photovoltaic (PV) cells, whereas the device stack(s) not connected to another device stack serves as the photodiode (PD) device (i.e., the PD is not serially connected to the PV). Thus, the device stacks 302a and 302b shown in the figures are both PV cells. However, an additional stack(s) (not shown) fabricated in the same manner on insulating substrate 202 (but not serially connected to another stack) would serve as the PD device.

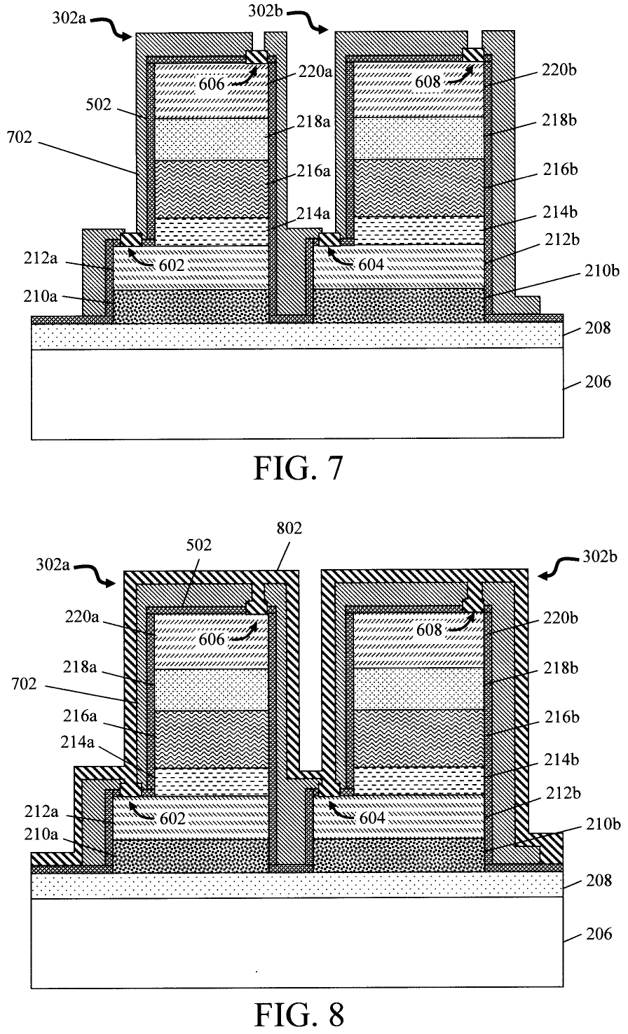

To form the interconnects, standard photolithography techniques are first used to pattern a photoresist mask 702 over the device stacks 302a and 302b. See FIG. 7. Photoresist mask 702 covers those areas of the device stacks 302a and 302b from which a plated interconnect metal (see below) will be removed, e.g., via a lift-off process.

Namely, as shown in FIG. 8 a thin (e.g., from about 2 nm to about 5 nm and ranges therebetween) seed layer 802 of a contact metal is then deposited onto the device stacks 302a and 302b over the photoresist mask 702. As provided above, suitable contact metals include, but are not limited to, Cu, Al, W, Ti, Pd, Ni and/or Pd. According to an exemplary embodiment, the same contact metal is used for seed layer 802 as for contact pads 602/604 and 606/608. Use of the same contact metal is, however, not required. Seed layer 802 can be deposited onto the device stacks 302a and 302b using a process such as evaporation or sputtering.

Deposition of the seed layer 802 enables use of an electroplating process for the interconnects. However, since the seed layer 802 is blanket deposited over the device stacks 302a and 302b, measures are first taken to pattern the seed layer 802 such that electroplating will occur directly on only those portions of the seed layer 802 at the locations of the interconnects. Everywhere else, the seed layer 802 and any excess contact metal will be lifted off with the photoresist.

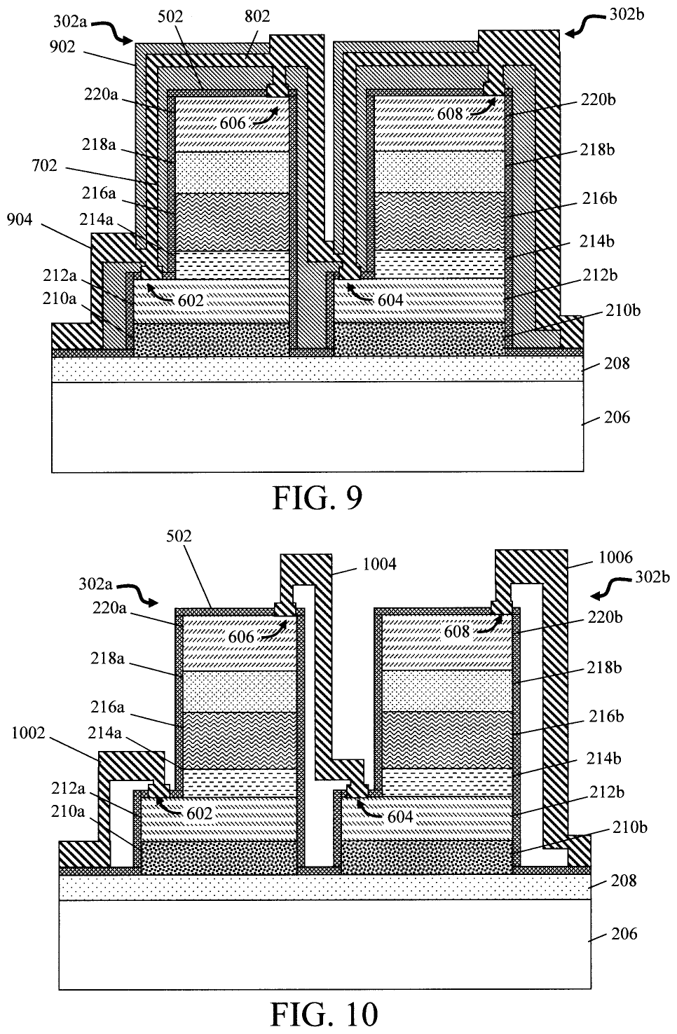

To pattern the seed layer 802, standard photolithography techniques are used to pattern a second photoresist mask 902 (wherein photoresist mask 702 is the first photoresist mask) over the device stacks 302a and 302b covering seed layer 802 everywhere but where the interconnects will be formed. See FIG. 9. Electroplating is then used to plate a contact metal 904 onto the exposed areas of seed layer 802. As provided above, suitable contact metals include, but are not limited to, Cu, Al, W, Ti, Pd, Ni and/or Pd. According to an exemplary embodiment, the same contact metal is used for contact metal 904 and seed layer 802 as for contact pads 602/604 and 606/608. Use of the same contact metal is, however, not required.

Outside of the interconnects, the seed layer 802 and any excess contact metal 904 are then removed along with photoresist masks 702 and 902, i.e., a lift-off process. What remains following the metal lift-off are interconnects 1002, 1004 and 1006. See FIG. 10. Namely, as shown in FIG. 10, interconnect 1002 is in contact with contact pad 602, interconnect 1004 is in contact with contact pads 604 and 606, and interconnect 1006 is in contact with contact pad 608. As such, the device stacks 302a and 302b are serially connected (electrically) via the interconnects 1002, 1004 and 1006.

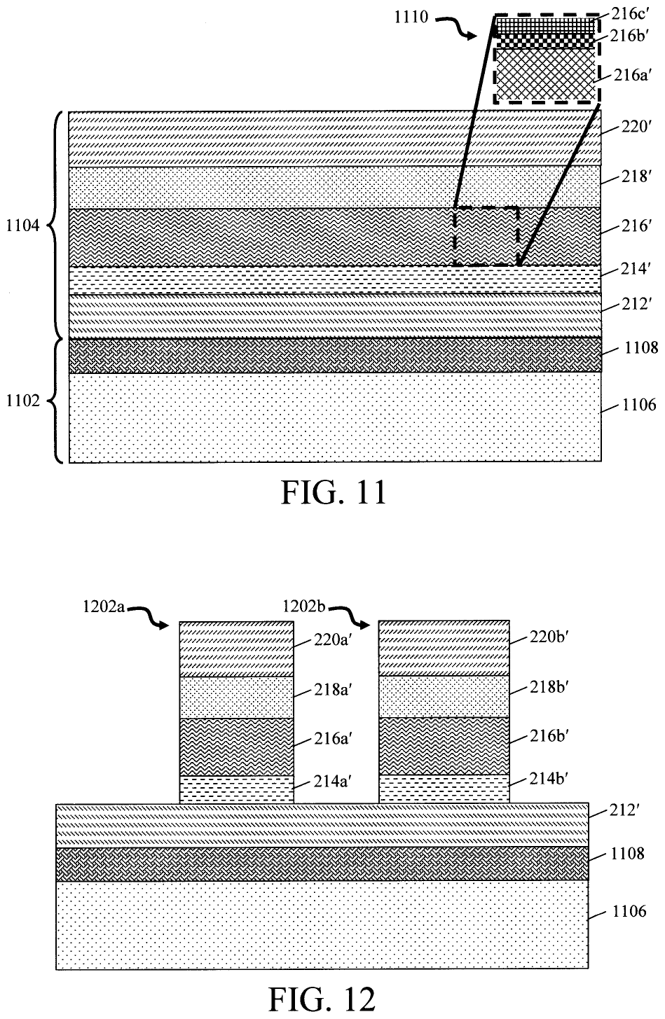

As highlighted above, embodiments are also contemplated herein where a III-V substrate is employed and lateral oxidation is used to form an insulating oxide layer on the III-V substrate. This alternative embodiment is now described by way of reference to FIGS. 11-15. It is notable that most of the fabrication process is the same as the example described in accordance with the description of FIGS. 1-10, above. Thus, the same structures/materials will be numbered alike with the addition of a prime symbol (i.e., X′) for clarity, and it will be noted where/when deviations from the above-described process occur. Further, some steps depicted individually above may be combined into a single figure.

As above, the present photovoltaic devices are formed on an insulating substrate. In the above example, an SOI wafer was employed wherein the buried insulator provides isolation of the devices. In the present example, the process begins instead with a III-V substrate and lateral oxidation performed later in the process is used to oxidize a top layer of the substrate for the insulator.

Namely, as shown in FIG. 11, the process begins with a substrate 1102 on which a photovoltaic stack 1104 is formed. As highlighted above, substrate 1102 is a III-V substrate formed from one or more of the III-V materials provided above. For instance, according to an exemplary embodiment, substrate 1102 includes a layer 1106 formed from a first III-V material or combination of III-V materials, and a layer 1108 (disposed on layer 1106) formed from a second/different III-V material or combination of III-V materials. To use an illustrative, non-limiting example, in one embodiment layer 1106 is GaAs, and layer 1108 is AlAs. Later in the process, lateral oxidation will be used to oxidize the material in layer 1108 to form an insulator. Thus, in the case of a (bottom) GaAs/(top) AlAs substrate 1102 configuration, the AlAs will be oxidized to form aluminum oxide (Al₂O₃). The formation of Al₂O₃ by oxidation of AlAs/GaAs films is discussed, for example, in Schubert et al., “Properties of Al₂O₃ optical coatings on GaAs produced by oxidation of epitaxial AlAs/GaAs films,” Appl. Phys. Lett. 64 (22), pp. 2976-2978 (May 1994), and Tsang et al., “Multidielectrics for GaAs MIS devices using composition-graded AlxGa1-xAs and oxidized AlAs,” Appl. Phys. Lett. 34(6), pp. 408-410 (March 1979), the contents of both of which are incorporated by reference as if fully set forth herein.

The layers of photovoltaic stack 1104 are then deposited sequentially, one on top of the other, onto the substrate 1102. According to an exemplary embodiment, photovoltaic stack 1104 has the same composition as photovoltaic stack 204 in the above example, i.e., a bottom contact layer 212′ disposed on layer 1108, BSF layer 214′ disposed on the bottom contact layer 212′, junction layer 216′ disposed on the BSF layer 214′, window layer 218′ disposed on the junction layer 216′, and top contact layer 220′ disposed on the window layer 218′.

Bottom contact layer 212′ can be formed from one or more of the III-V materials provided above, e.g., GaAs, which is optionally doped with at least one electrically-active impurity such as Si, e.g., Si:GaAs, at a concentration of from about 5×10¹⁸ at. % to about 8×10¹⁸ at. % and ranges therebetween. According to an exemplary embodiment, the bottom contact layer 212′ is deposited onto substrate 1102 using an epitaxial growth process (such as MBE), a CVD process such as MOCVD, or ALD to a thickness of from about 20 nm to about 30 nm and ranges therebetween, e.g., 30 nm. It is notable that the various layers, structures, etc. depicted in the figures are not necessarily drawn to scale.

BSF layer 214′ can be formed from one or more of the III-V materials provided above, e.g., InGaP, which is optionally doped with at least one electrically-active impurity such as Zn, e.g., Zn:InGaP, at a concentration of from about 1×10¹⁸ at. % to about 5×10¹⁸ at. % and ranges therebetween. According to an exemplary embodiment, BSF layer 214′ is deposited onto bottom contact layer 212′ using an epitaxial process (e.g., MBE), CVD (e.g., MOCVD) or ALD to a thickness of from about 80 nm to about 120 nm and ranges therebetween, e.g., 100 nm.

As shown in expanded view 1110, junction layer 216′ includes a base layer 216a′ disposed on BSF layer 214′, a setback layer 216b′ disposed on base layer 216a′, and an emitter layer 216c′ disposed on the setback layer 216b′. Base layer 216a′ can be formed from one or more of the III-V materials provided above, e.g., GaAs, which is optionally doped with at least one electrically-active impurity such as Zn, e.g., Zn:GaAs, at a concentration of from about 1×10¹⁷ at. % to about 2×10¹⁷ at. % and ranges therebetween. According to an exemplary embodiment, base layer 216a′ is deposited onto BSF layer 214′ using an epitaxial process (e.g., MBE), CVD (e.g., MOCVD) or ALD to a thickness of from about 0.5 μm to about 1.5 μm and ranges therebetween, e.g., 1.0 μm.

Setback layer 216b′ too can be formed from one or more of the III-V materials provided above, e.g., intrinsic (undoped) GaAs. According to an exemplary embodiment, setback layer 216b′ is deposited onto base layer 216a′ using an epitaxial process (e.g., MBE), CVD (e.g., MOCVD) or ALD to a thickness of from about 5 nm to about 15 nm and ranges therebetween, e.g., 10 nm.

Emitter layer 216c′ can be formed from one or more of the III-V materials provided above, e.g., GaAs, which is optionally doped with at least one electrically-active impurity such as Si, e.g., Si:GaAs, at a concentration of from about 1×10¹⁸ at. % to about 2×10¹⁸ at. % and ranges therebetween. According to an exemplary embodiment, emitter layer 216c′ is deposited onto setback layer 216b′ using an epitaxial process (e.g., MBE), CVD (e.g., MOCVD) or ALD to a thickness of from about 80 nm to about 120 nm and ranges therebetween, e.g., 100 nm.

Window layer 218′ can be formed from one or more of the III-V materials provided above, e.g., Al_{0.6}Ga_{0.4}As, which is optionally doped with at least one electrically-active impurity such as Si, e.g., Si:Al_{0.6}Ga_{0.4}As, at a concentration of from about 2×10¹⁸ at. % to about 4×10¹⁸ at. % and ranges therebetween. According to an exemplary embodiment, window layer 218′ is deposited onto junction layer 216′ using an epitaxial process (e.g., MBE), CVD (e.g., MOCVD) or ALD to a thickness of from about 180 nm to about 220 nm and ranges therebetween, e.g., 200 nm.

Like bottom contact layer 212′, top contact layer 220′ can be formed from one or more of the III-V materials provided above, e.g., GaAs, which is optionally doped with at least one electrically-active impurity such as Si, e.g., Si:GaAs, at a concentration of from about 5×10¹⁸ at. % to about 8×10¹⁸ at. % and ranges therebetween. According to an exemplary embodiment, top contact layer 220′ is deposited onto window layer 218′ using an epitaxial process (e.g., MBE), CVD (e.g., MOCVD) or ALD to a thickness of from about 20 nm to about 30 nm and ranges therebetween, e.g., 30 nm.

In the same manner as above, standard lithography and etching techniques are then used to pattern the photovoltaic stack 1104 into individual device stacks 1202a, 1202b, etc. See FIG. 12. As shown in FIG. 12, each device stack 1202a,b, etc. extends down through the top contact layer 220′, window layer 218′, junction layer 216′ and BSF layer 214′. The patterned portions of each of these layers in device stacks 1202a/1202b are now given the reference numerals 220a′/220b′, 218a′/218b′, 216a/216b′ and 214a′/214b′, respectively.

Device stacks 1202a and 1202b form separate multilayer 3D monolithic devices that, as will be described in detail below, can each serve as a photovoltaic (PV) cell or photodiode (PD) device on the (common) insulating substrate 1102. Thus, as will be described below, the present devices can be employed for a combination of power generation (photovoltaic cell) and signal receiving (photodiode). For instance, using the configuration shown in FIG. 1 (described above) as an example, interconnects can be formed to serially connect those devices that will serve as photovoltaic cells for multilevel power generation.

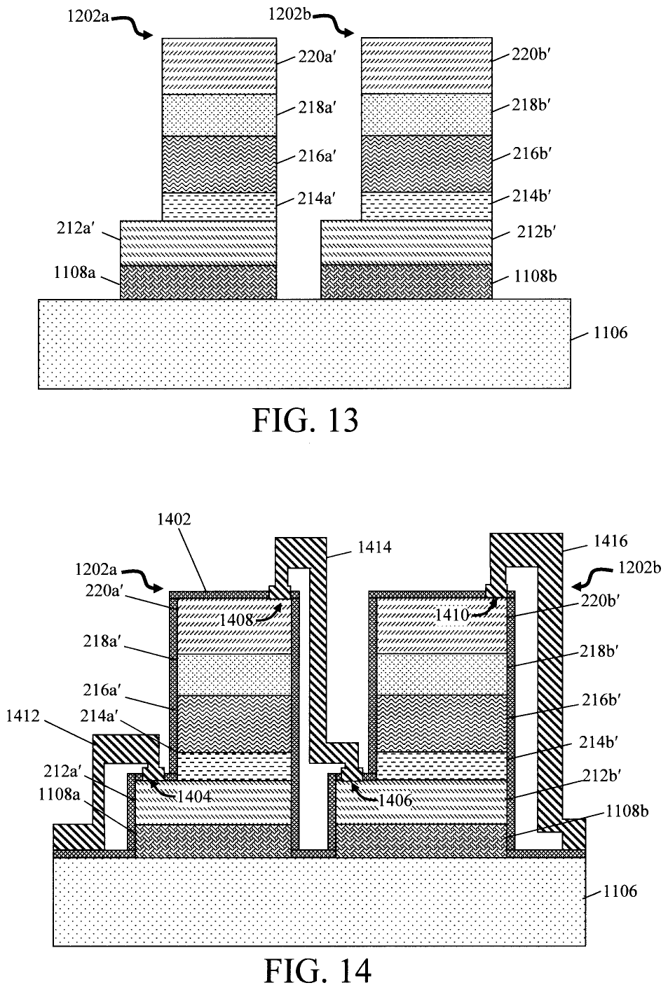

An isolation etch is next performed to pattern the bottom contact layer 212′ and layer 1108 in the device stacks 1202a/1202b. See FIG. 13. As shown in FIG. 13, the patterned portions of each of these layers in device stacks 1202a/1202b are now given the reference numerals 212a′/212b′ and 1108a/1108b, respectively.

Once patterning of the device stacks 1202a/1202b is complete, the process proceeds in the same manner as above to form a conformal surface passivation layer 1402 (e.g., Al₂O₃) on device stacks 1202a/1202b, contact pads 1404/1406 and 1408/1410 to bottom contacts 212a′/212b′ and top contacts 220a′/220b′, and interconnects 1412, 1414 and 1416 to the contact pads 1404/1406 and 1408/1410. The steps involved in forming interconnects 1412, 1414 and 1416, e.g., formation of a photoresist mask(s), deposition of a seed layer, electroplating of interconnect metal, lift-off, etc., were described in detail above. As shown in FIG. 14, interconnect 1412 is in contact with contact pad 1404, interconnect 1414 is in contact with contact pads 1408 and 1406, and interconnect 1416 is in contact with contact pad 1410. As such, the device stacks 1202a and 1202b are serially connected (electrically) via the interconnects 1412, 1414 and 1416.

In the present example, the interconnects 1412, 1414 and 1416 serially connect the device stacks 1202a and 1202b. As provided above, the device stacks that are serially connected serve as photovoltaic (PV) cells, whereas the device stack(s) not connected to another device stack serves as the photodiode (PD) device (i.e., the PD is not serially connected to the PV). Thus, the device stacks 1202a and 1202b shown in the figures are both PV cells. However, an additional stack(s) (not shown) fabricated in the same manner on insulating substrate 1102 (but not serially connected to another stack) would serve as the PD device.

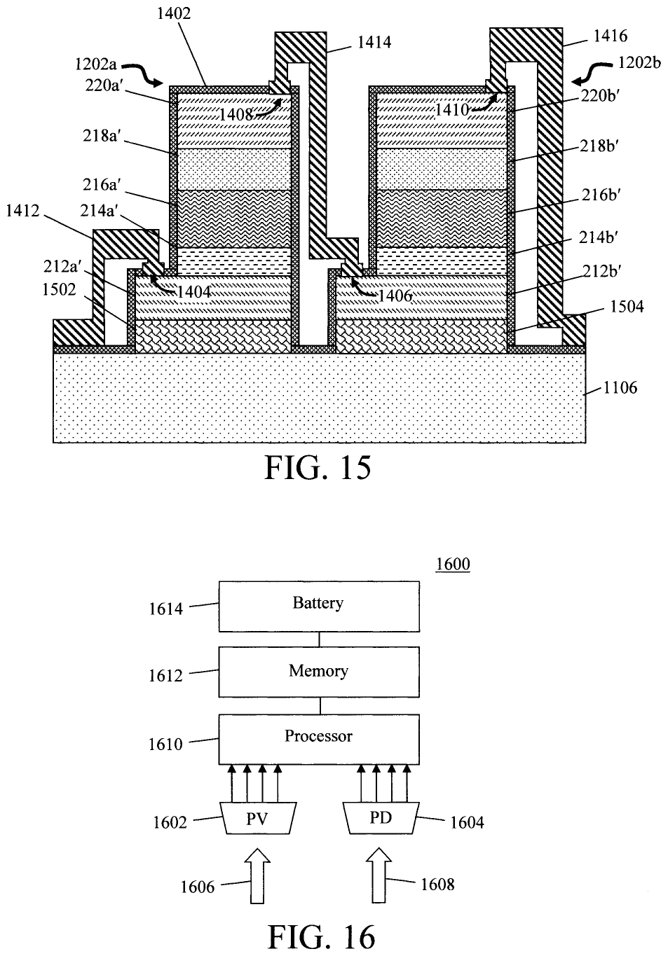

Finally, as shown in FIG. 15, lateral oxidation is used to convert the patterned portions 1108a/1108b of layer 1108 into oxide insulator 1502 and 1504, respectively. For instance, according to an exemplary embodiment, layer 1108 of substrate 1102 is AlAs which, via the lateral oxidation, is converted to Al₂O₃ insulator 1502 and 1504.

By way of example only, the present monolithic photovoltaic devices can be incorporated into a computing device such as computing device 1600 of FIG. 16. As shown in FIG. 16, computing device 1600 includes at least one photovoltaic cell 1602 for energy generation using incident light 1606, and at least one photodiode 1604 for receiving optical signals 1608, each of which is formed using the process described in conjunction with the description of FIGS. 2-10 (e.g., GeOI insulating substrate) or the process described in conjunction with the description of FIGS. 11-15 (GaAs/Al₂O₃ insulating substrate), above.

Namely, photovoltaic cell(s) 1602 generate the energy to run a processor 1610 and a memory 1612, as well as photodiode(s) 1604. Excess energy generated by photovoltaic cell(s) 1602 can be stored by battery 1614. According to an exemplary embodiment, the wavelength of light absorbed by the photovoltaic cell(s) 1602 is from about 300 nm to about 900 nm, and ranges therebetween, and the power produced by the photovoltaic cell(s) 1602 is from about 1.5 volts (V) to about 2.0 V, and ranges therebetween.

The photodiode(s) 1604 generate a given output in response to optical signal 1608, thereby photodiode(s) 1604 to serve as an optical receiver. Data received by the photodiode(s) 1604 can be processed by processor 1610 and/or stored in memory 1612 that is coupled to processor 1610. According to an exemplary embodiment, optical signals 1608 are light-based signals that are transmitted to photodiode(s) 1604 using a light source, such as a laser. According to an exemplary embodiment, the wavelength of light for optical signals 1608 is from about 400 nm to about 870 nm and ranges therebetween.

Although illustrative embodiments of the present invention have been described herein, it is to be understood that the invention is not limited to those precise embodiments, and that various other changes and modifications may be made by one skilled in the art without departing from the scope of the invention.

1-6. (canceled)

7. A photovoltaic device, comprising:
an insulating substrate;
device stacks on the insulating substrate, wherein each of the device stacks comprises: a bottom contact layer disposed on the insulating substrate, a back surface field (BSF) layer disposed on the bottom contact layer, a junction layer disposed on the BSF layer, a window layer disposed on the junction layer, and a top contact layer disposed on the window layer;
contact pads formed on a top surface of the bottom contact layer and on a top surface of the top contact layer in each of the device stacks; and
interconnects in contact with the contact pads that serially connect the device stacks.

8. The photovoltaic device of claim 7, wherein the bottom contact layer, the BSF layer, the junction layer, the window layer, and the top contact layer each comprises a III-V material selected from the group consisting of: AlAs, AlGaAs, AlGaN, InAlAs, AlN, GaSb, GaAs, GaN, InSb, InAs, InGaAs, InGaN, InGaP, InN, InP, InₓGa₁₋ₓAs_{y}P_{1-y}, and combinations thereof.

9. The photovoltaic device of claim 7, wherein the insulating substrate comprises a semiconductor-on-insulator (SOI) layer separated from an underlying substrate by a buried insulator, and wherein the SOI layer comprises Ge.

10. The photovoltaic device of claim 7, wherein the insulating substrate comprises:
a III-V layer; and
an oxide insulator disposed on top of the III-V layer.

11. The photovoltaic device of claim 10, wherein the III-V layer comprises GaAs, and wherein the oxide insulator comprises aluminum oxide.

12. The photovoltaic device of claim 7, wherein the bottom contact layer and the top contact layer each comprises GaAs, and wherein the bottom contact layer and the top contact layer are each doped with Si at a concentration of from about 5×10¹⁸ molar (atomic) percent (at. %) to about 8×10¹⁸ at. % and ranges therebetween.

13. The photovoltaic device of claim 7, wherein the BSF layer comprises InGaP, and wherein the BSF layer is doped with Zn at a concentration of from about 1×10¹⁸ at. % to about 5×10¹⁸ at. % and ranges therebetween.

14. The photovoltaic device of claim 7, wherein the junction layer comprises:
a base layer disposed on the BSF layer;
a setback layer disposed on base layer; and
an emitter layer disposed on the setback layer.

15. The photovoltaic device of claim 14, wherein the base layer comprises GaAs, and wherein the base layer is doped with Zn at a concentration of from about 1×10¹⁷ at. % to about 2×10¹⁷ at. % and ranges therebetween.

16. The photovoltaic device of claim 14, wherein the setback layer comprises intrinsic GaAs.

17. The photovoltaic device of claim 14, wherein the emitter layer comprises GaAs, and wherein the emitter layer is doped with Si at a concentration of from about 1×10¹⁸ at. % to about 2×10¹⁸ at. % and ranges therebetween.

18. The photovoltaic device of claim 14, wherein the window layer comprises Al_{0.6}Ga_{0.4}As, and wherein the window layer is doped with Si at a concentration of from about 2×10¹⁸ at. % to about 4×10¹⁸ at. % and ranges therebetween.

19. A photovoltaic device, comprising:
an insulating substrate;
device stacks on the insulating substrate, wherein each of the device stacks comprises: a bottom contact layer disposed on the insulating substrate, a BSF layer disposed on the bottom contact layer, a junction layer disposed on the BSF layer, a window layer disposed on the junction layer, and a top contact layer disposed on the window layer;
contact pads formed on a top surface of the bottom contact layer and on a top surface of the top contact layer in each of the device stacks; and
interconnects in contact with the contact pads that serially connect the device stacks,
wherein the bottom contact layer, the BSF layer, the junction layer, the window layer, and the top contact layer each comprises a III-V material selected from the group consisting of: AlAs, AlGaAs, AlGaN, InAlAs, AlN, GaSb, GaAs, GaN, InSb, InAs, InGaAs, InGaN, InGaP, InN, InP, InₓGa₁₋ₓAs_{y}P_{1-y}, and combinations thereof.

20. The photovoltaic device of claim 19, wherein the insulating substrate comprises either i) a SOI layer comprising Ge separated from an underlying substrate by a buried insulator, or ii) an oxide insulator disposed on top of a III-V layer.

21. The photovoltaic device of claim 7, wherein the interconnects are in a non-contact position with the bottom contact layer and the top contact layer in each of the device stacks.
